(19) United States
(12) Patent Application Publication
(10) Pub. No.: US 2021/0164766 A1
(43) Pub. Date: Jun. 3, 2021

(54) ELECTRONIC APPLIANCE WITH INDUCTIVE SENSOR

(71) Applicant: Helmut Fischer GmbH Institut fuer Elektronik und Messtechnik, Sindelfingen (DE)

(72) Inventor: Gerd REIME, Buehl (DE)

(73) Assignee: Helmut Fischer GmbH Institut fuer Elektronik und Messtechnik, Sindelfingen (DE)

(21) Appl. No.: 16/772,876

(22) PCT Filed: Dec. 19, 2018
(86) PCT No.: PCT/EP2018/085929

§ 371 Date: Jun. 15, 2020

(30) Foreign Application Priority Data
Dec. 20, 2017 (DE) 10 2017 130 822.9
Jul. 4, 2018 (DE) 10 2018 211 025.5

(51) Int. Cl. G01B 7/00; G01D 5/20; G01B 7/06; H05K 5/02; H03B 5/12; H03K 17/95

(52) U.S. Cl. CPC G01B 7/003; G01D 5/202; H03K 17/952; H05K 5/0217; H03B 5/12; G01B 7/105

(57) ABSTRACT

An electronic device comprising a housing and an actuating element movable relative to the housing, wherein the actuating element comprises at least one metallic component, wherein the device comprises an inductive sensor for detecting a position and/or movement of the actuating element, wherein the inductive sensor comprises: a first measuring resonant circuit having a sensor coil, and an oscillation generator configured to generate an excitation oscillation and to at least temporarily apply the excitation oscillation to the first measuring resonant circuit.

### FIELD OF THE INVENTION

The invention relates to an electronic device having a housing and an actuating element movable relative to the housing.

### STATE OF THE ART

Such devices are well known and can be provided, for example, in the form of hand-held measuring devices in which the actuating element can be actuated, in particular moved, by a user of the device. The actuating elements of known devices often act directly on an electric circuit or form a part of a circuit, respectively, which results in a complex structure and a susceptibility to soiling. Therefore, good electric contacting of electric contact elements which can be actuated by the actuating element is often not ensured over a long period of time.

DE 41 37 485 A1 describes a switching device having an inductive proximity switch. DE 296 20 044 U1 describes a layer thickness measuring device. DE 33 18 900 A1 describes a proximity switch.

### DISCLOSURE OF THE INVENTION

Preferred exemplary embodiments relate to an electronic device according to claim 1.

An electronic device is proposed, comprising a housing and an actuating element movable relative to the housing, wherein the actuating element comprises at least one metallic component, wherein the device comprises an inductive sensor for detecting a position and/or movement of the actuating element, wherein the inductive sensor comprises: a first measuring resonant circuit comprising a sensor coil, in which a first measuring oscillation can be generated, and an oscillation generator configured to generate an excitation oscillation and to at least temporarily apply the excitation oscillation to the first measuring resonant circuit, wherein the device comprises an evaluation device configured to determine, dependent on the first measuring oscillation, movement information characterizing the position and/or movement of the actuating element.

The device comprises at least one functional component, wherein the device is configured to control an operating state and/or a change of an operating state of the at least one functional component depending on the movement information.

The provision of an inductive sensor according to the invention advantageously allows a reliable operation of the device, wherein at the same time a particularly low electric energy consumption is required for its operation due to the construction of the inductive sensor according to the invention. By means of the measuring oscillation, an interaction of the metallic component of the actuating element with the sensor coil can be detected, and from this, a position and/or movement of the actuating element can be determined by the evaluation device. The excitation oscillation can advantageously be generated in a very energy-efficient manner and does not require any electric energy supply during a decay.

The measuring oscillation can be generated by applying the excitation oscillation, in the case of particularly advantageous embodiments in particular by resonance with the excitation oscillation, and therefore does not require a separate energy supply.

According to studies carried out by the applicant, this allows a current consumption for the inductive sensor of approximately 200 nA (nanoamperes) at an operating voltage of approximately 3 V (volts).

With preferred embodiments, the measuring oscillation has a swelling and subsequently decaying signal course, which can be evaluated very easily by the evaluation device, for example, always between the swelling and the decay, in particular when a signal maximum of the envelope of the measuring oscillation appears. The swelling signal course results, for example, from the fact that energy provided in the form of the excitation oscillation is transferred to the first measuring resonant circuit, whereby the latter can be excited to the swelling oscillation, and the decaying signal course results, for example, from the fact that the excitation oscillation itself decays, whereby—in contrast to the swelling oscillation—less energy per time or no energy at all, respectively, is transferred to the first measuring resonant circuit, and the latter therefore also dies away.

In general, an oscillation of the first measuring resonant circuit can be characterized, for example, by a time-varying electric voltage appearing at the sensor coil and/or by a time-varying electric current flowing through the sensor coil. In some embodiments, the evaluation device can, for example, evaluate said electric voltage and/or said electric current in order to determine movement information characterizing a position and/or movement of the actuating element.

Furthermore, a particular advantage of the present embodiments, which involve a swelling and then decaying oscillation in the measuring resonant circuit, is that a signal maximum (e.g. maximum voltage) of the swelling and then decaying oscillation in comparison to a merely decaying oscillation, for example, is much more strongly depending on an interaction of the sensor coil with the actuating element or its at least one metallic component, which results in a greater sensitivity of the proposed measuring principle than with conventional inductive methods, and which enables a more precise detection of the position and/or movement of the actuating element which is more independent of disturbances.

In some embodiments, the actuating element itself may, for example, be electrically non-conductive, but may have at least one metallic or electrically conductive component whose electrically conductive material may interact with the measuring oscillation of the first sensor coil and may thus be evaluated. In other embodiments, the actuating element itself can also be made at least partially or regionally electrically conductive, and may also have an additional electrically conductive component.

With preferred embodiments, an interaction of the actuating element (or its metallic or electrically conductive component, respectively) with the sensor coil, which can be evaluated by the evaluation device, is such that an alternating magnetic field in the region of the sensor coil caused by the measuring oscillation induces eddy currents in the actuating element or its metallic or electrically conductive component. This can, for example, cause an attenuation of the first measuring oscillation. Depending on the arrangement of the actuating element in relation to the sensor coil, this interaction can be stronger or weaker, which can be evaluated. In particular, both a position of the actuating element and movements of the actuating element can be detected.

With other embodiments, it is conceivable that an approach of the actuating element or its metallic component to the sensor coil or a withdrawal of the same from the sensor coil, respectively, affects the resonant frequency of the first measuring resonant circuit, so that instead of the above-mentioned attenuation, also an amplification of the first measuring oscillation may result when the actuating element approaches the first sensor coil.

In other embodiments, the oscillation generator is configured to generate a plurality of temporally consecutive excitation oscillations and to apply the plurality of excitation oscillations to the first measuring resonant circuit, resulting in particular in a plurality of measuring oscillations corresponding to the number of the plurality of temporally consecutive excitation oscillations.

With other embodiments, it may also be intended to apply a single excitation oscillation to the first measuring resonant circuit, resulting in a single measuring oscillation.

According to studies carried out by the applicant, the evaluation of a single measuring oscillation may be sufficient to determine movement information with sufficient accuracy for some applications. In contrast, in other embodiments, if a plurality of excitation oscillations and a plurality of measuring oscillations are applied, a comparable evaluation can be carried out repeatedly, for example, which in some cases increases the accuracy and/or improves detectability of movements.

With other embodiments, the oscillation generator is configured to periodically generate the plurality of excitation oscillations with a first clock frequency and to apply the periodically generated excitation oscillations to the first measuring resonant circuit. With other embodiments, the first clock frequency is between about 0.5 Hertz and about 800 Hertz, preferably between about 2 Hertz and about 100 Hertz, and more preferably between about 5 Hertz and about 20 Hertz.

With other embodiments, the oscillation generator is configured to apply the excitation oscillation to the first measuring circuit such that the first measuring oscillation is a swelling and subsequently decaying oscillation. This results in a particularly sensitive evaluation, as already mentioned above.

With other embodiments, the first measuring resonant circuit can be brought into resonance with the excitation oscillation, in particular for generating a swelling and subsequently decaying measuring oscillation.

With other embodiments, the first measuring resonant circuit is a first LC oscillator with a first resonant frequency, wherein the sensor coil is an inductive element of the first LC oscillator, and wherein a capacitive element of the first LC oscillator is connected in parallel with the sensor coil. In this case, in a manner known per se, the first resonant frequency, which is the natural resonant frequency of the first LC oscillator, results from the inductance of the sensor coil and the capacitance of the capacitive element.

With other embodiments, the oscillation generator is configured to generate the excitation oscillation at a second frequency, wherein the second frequency is between about 60 percent and about 140 percent of the first resonant frequency of the first LC oscillator. Preferably, the second frequency is between about 80 percent and about 120 percent of the first resonant frequency of the first LC oscillator, and more preferably between about 95 percent and about 105 percent of the first resonant frequency.

With other embodiments, the oscillation generator has a second LC oscillator and a clock generator which is configured to apply to the second LC oscillator a first clock signal or a signal derived from the first clock signal (for example an amplified first clock signal) which has the first clock frequency and a pre-determinable duty cycle.

With other embodiments, the pre-determinable duty cycle is between about 100 nanoseconds and about 1000 milliseconds, in particular between about 500 nanoseconds and about 10 microseconds, and more preferably about one microsecond.

With other embodiments, the first measuring resonant circuit is, especially at least temporarily, inductively coupled to the oscillation generator. With other embodiments, the first measuring resonant circuit is capacitively coupled to the oscillation generator, preferably via a coupling element comprising an electric serial connection of a coupling resistor and a coupling capacitor. This allows precise adjustment of the coupling impedance.

With other embodiments, the evaluation device is configured to compare at least two maximum or minimum amplitude values of different oscillation periods of the (same) measuring oscillation with each other.

With other embodiments, the evaluation device is configured to compare a maximum or minimum amplitude value of a first measuring oscillation of the plurality of measuring oscillations with a corresponding maximum or minimum amplitude value of a second measuring oscillation of the plurality of measuring oscillations, wherein preferably the second measuring oscillation follows the first measuring oscillation, in particular directly follows the first measuring oscillation (without a further measuring oscillation occurring between the first and second measuring oscillations).

With other embodiments, the evaluation device is configured to compare a first amplitude value of the measuring oscillation of a first clock cycle with an amplitude value of the measuring oscillation of a second clock cycle, wherein the comparing in particular comprises forming a difference. A clock cycle can be understood as the sequence of a clock pulse and the subsequent clock pause or as a clock period, respectively.

For example, with some embodiments, it is possible to determine whether or not a position of the actuating element has changed between two clock cycles on the basis of an exceeding or falling below a pre-defined threshold value for the difference. Thus, for example, changes of the position can be detected. Depending on the design, with some embodiments (only) a withdrawal or (only) an approach of the actuating element or both can be detected. For example, with preferred embodiments, if the actuating element remains in one (same) position, the threshold value is not passed upwardly or downwardly.

With other embodiments, at least one second measuring resonant circuit is provided which has a second sensor coil and in which a secondary measuring oscillation can be generated, wherein the oscillation generator is configured to at least temporarily apply the excitation oscillation also to the second measuring resonant circuit, wherein the evaluation device is configured to determine, depending on the first measuring oscillation and the secondary measuring oscillation, the movement information which characterizes the position and/or movement of the actuating element.

With other embodiments, the evaluation device comprises a comparator which is configured to compare an amplitude value of the measuring oscillation with a preset value.

With other embodiments, a preset value generating device is provided which is configured to generate the preset value, wherein the preset value generating device is in particular configured to generate the preset value at least temporarily a) as a static value and/or at least temporarily b) depending on an amplitude value of the measuring oscillation.

With other embodiments, a flip-flop element is provided, a set input of which is connected or can be connected to an output of the comparator and a reset input of which can be supplied with a clock signal, in particular the first clock signal.

With other embodiments, a low-pass filter is provided and an output of the flip-flop element is connected to an input of the low-pass filter.

With other embodiments, the device is configured to carry out the following steps: periodically generating a plurality of excitation oscillations, in particular decaying excitation oscillations, by means of the oscillation generator, and applying the plurality of excitation oscillations to the first measuring resonant circuit, wherein in particular the plurality of excitation oscillations can be applied to the first measuring resonant circuit such that a) the first measuring resonant circuit is brought, preferably at least approximately, into resonance with a respective excitation oscillation and/or b) the measuring oscillation is obtained as a swelling and subsequently decaying oscillation.

With other embodiments, the at least one functional component is a measuring device which is configured to measure layer thicknesses, wherein the measuring device is configured in particular to measure layer thicknesses of layers of lacquer and/or paint and/or rubber and/or or plastic on steel and/or iron and/or cast iron, and/or layers of lacquer and/or paint and/or rubber and/or or plastic on non-magnetic base materials such as, for example, aluminum, and/or copper and/or brass.

With other embodiments, the device is configured to carry out at least one layer thickness measurement by or by means of the measuring device depending on the movement information.

With other embodiments, the device is configured to at least temporarily deactivate the oscillation generator, wherein in particular the device is configured to at least temporarily deactivate the oscillation generator depending on the movement information.

With other embodiments, the housing has a substantially circular cylindrical basic shape, wherein the actuating element has a substantially hollow cylindrical basic shape and is coaxially surrounding a first axial end region of the housing.

With other embodiments, the sensor coil is arranged inside the housing and at least partially in the first axial end region.

With other embodiments, a compression spring is provided radially between the housing and the hollow cylindrical actuating element.

With other embodiments, the housing is hermetically sealed, at least in the first axial end region.

Further embodiments are directed to the use of an electronic device according to the embodiments for measuring at least one physical quantity, in particular a layer thickness of at least one lacquer layer.

Further features, possible applications and advantages of the invention can be derived from the following description of exemplary embodiments of the invention, which are shown in the figures of the drawings. All described or depicted features, either individually or in any combination, form the subject-matter of the invention, irrespective of their combination in the claims or the references of the claims, and irrespective of their formulation or representation in the description or in the drawings, respectively.

In the drawings:

FIG. 1 shows schematically a block diagram of an electronic device according to a first embodiment,

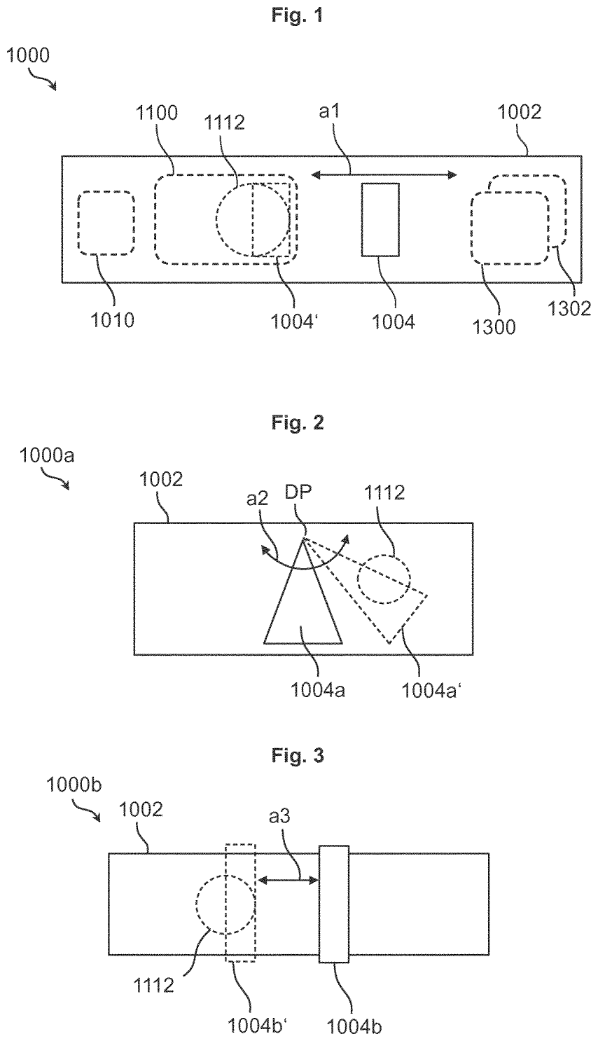

FIG. 2 shows schematically a block diagram of an electronic device according to another embodiment,

FIG. 3 shows schematically a block diagram of an electronic device according to another embodiment,

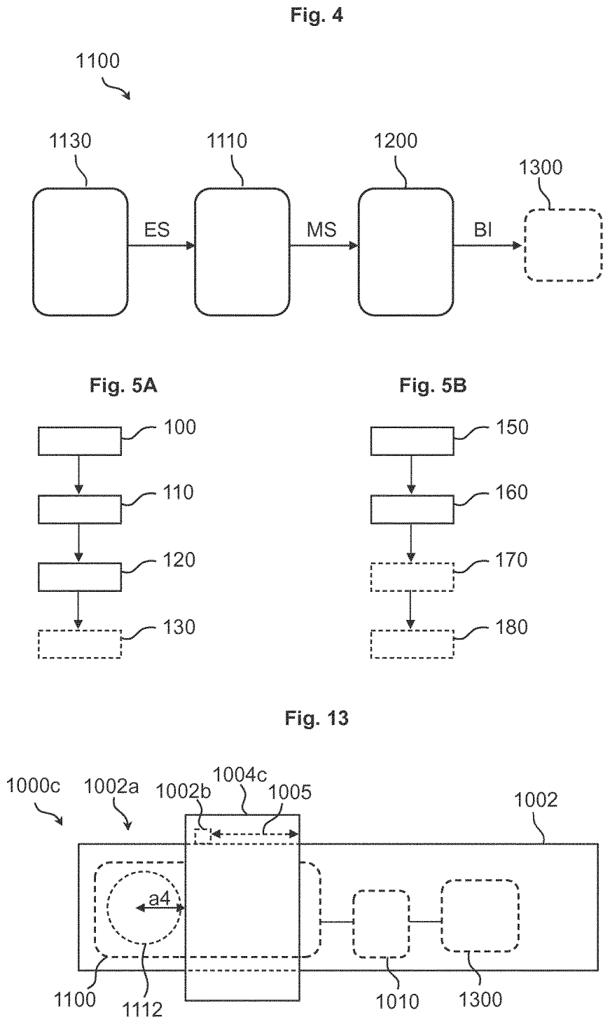

FIG. 4 shows schematically a block diagram of an inductive sensor according to an embodiment,

FIG. 5A shows schematically a simplified flow chart of a method according to an embodiment,

FIG. 5B shows schematically a simplified flow chart of a method according to a further embodiment,

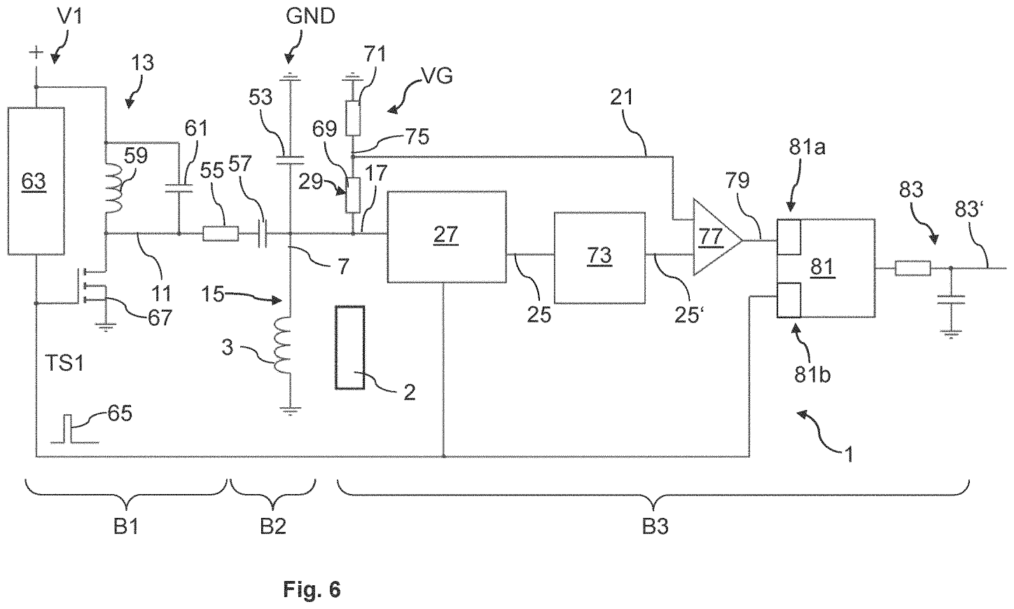

FIG. 6 shows schematically a circuit diagram of an inductive sensor according to an embodiment,

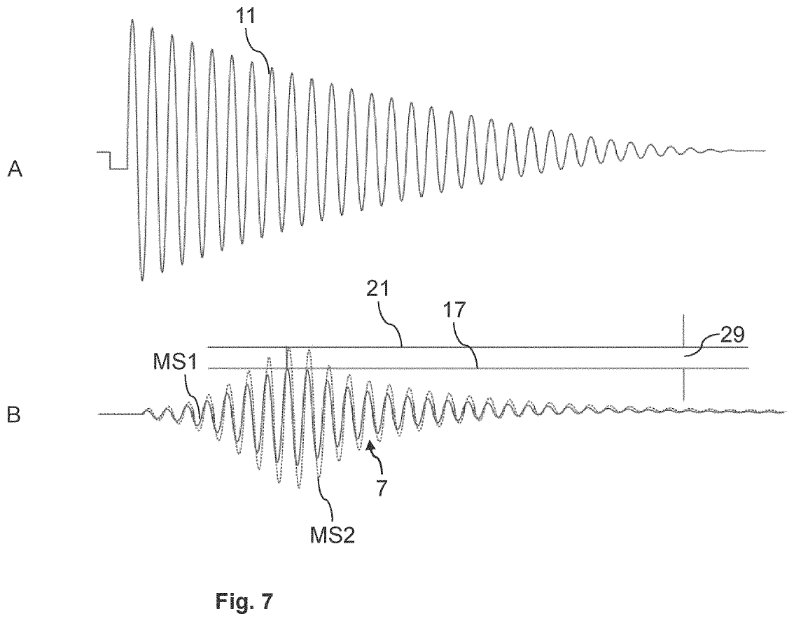

FIGS. 7A, 7B show schematically signal courses of an excitation oscillation and a measuring oscillation for a first clock cycle and a second clock cycle of the inductive sensor of FIG. 6,

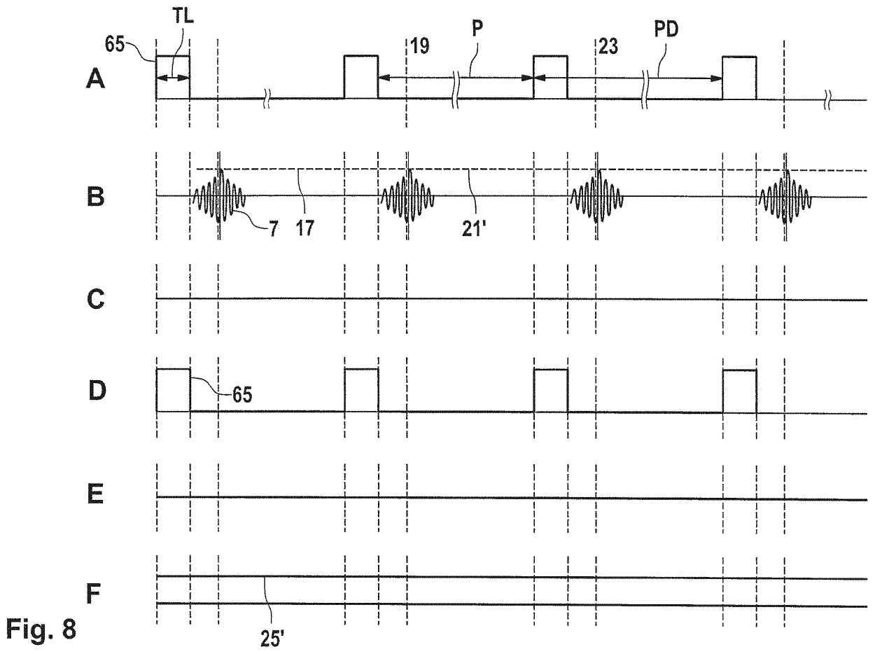

FIGS. 8A to 8F show schematically different time responses of different signals of the inductive sensor shown in FIG. 6 in a first operating state;

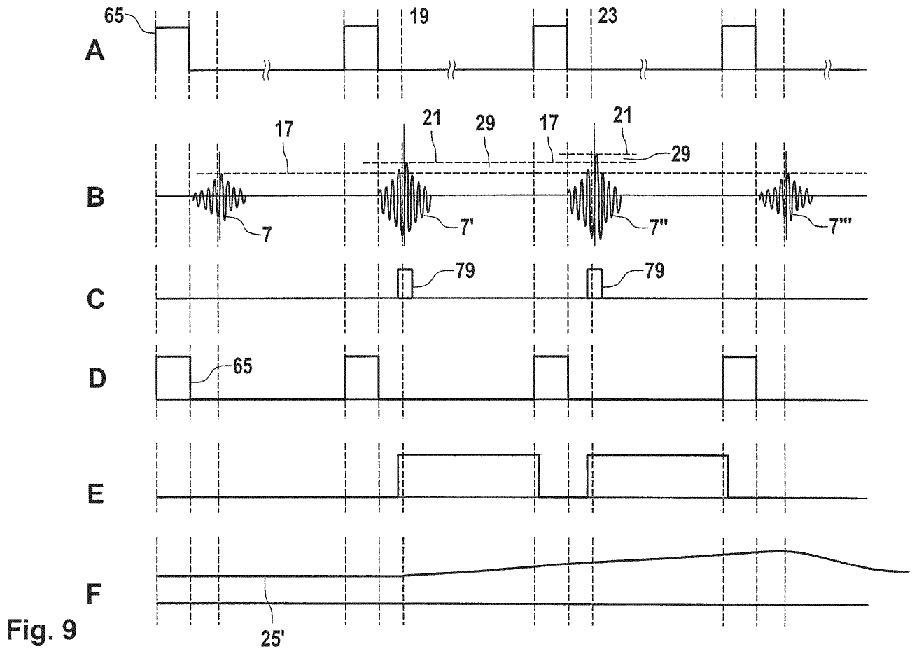

FIGS. 9A to 9F show schematically each of the signal courses shown in FIGS. 8A to 8F in a second operating state,

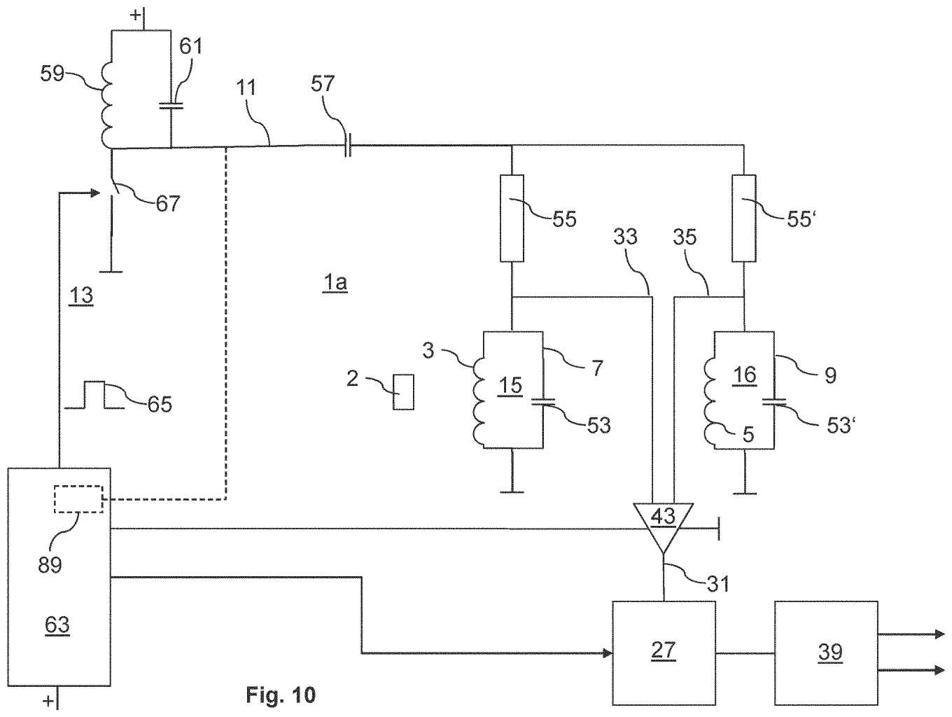

FIG. 10 shows schematically a circuit diagram of an inductive sensor according to a further embodiment,

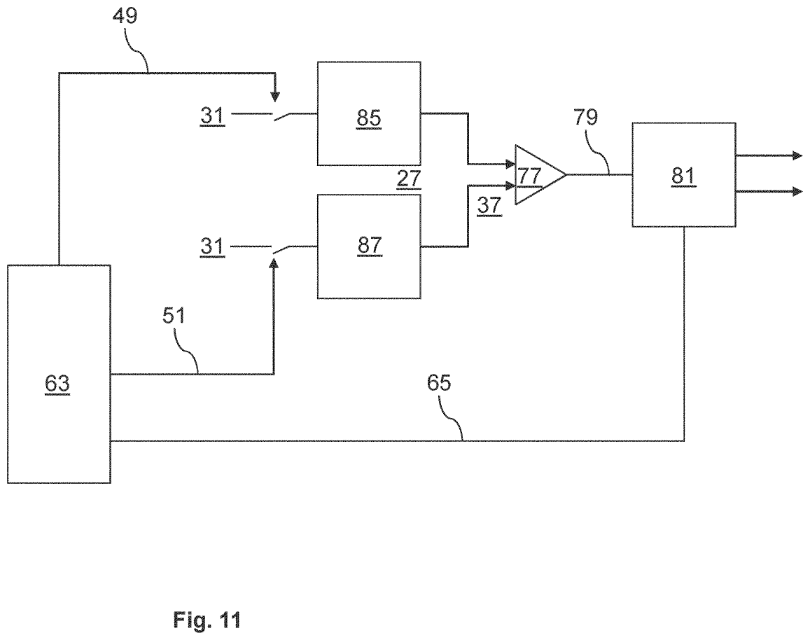

FIG. 11 shows schematically a maximum value memory according to an embodiment,

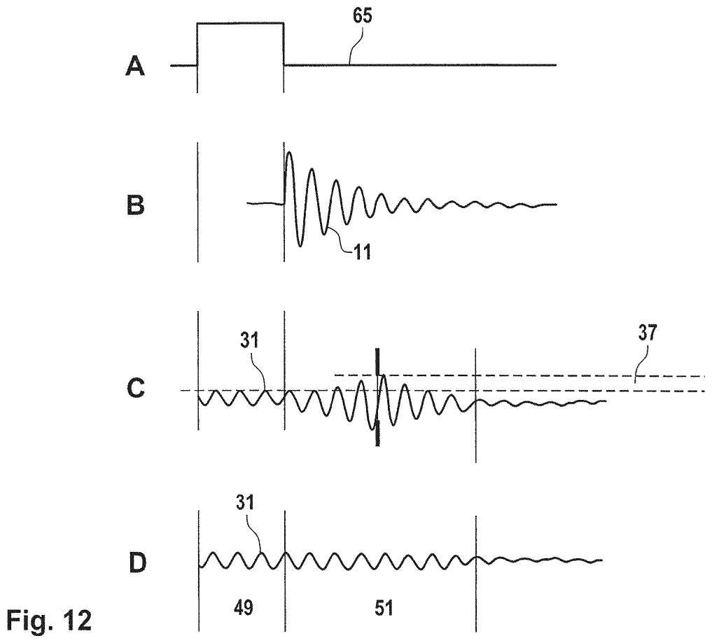

FIGS. 12A to 12D show schematically signal courses of an excitation oscillation and of a differential signal in different time windows, and

FIG. 13 shows a simplified block diagram of an electronic device according to another embodiment.

FIG. 1 schematically shows a block diagram of an electronic device 1000 according to a first embodiment. The device 1000 comprises a housing 1002 and an actuating element 1004 which is movable relative to the housing 1002. For example, actuator 1004 can be moved back and forth relative to housing 1002 along a longitudinal axis of the housing 1002, as indicated by the double arrow a1. A first (in FIG. 1 the right) axial end position of actuator 1004 is denoted with reference sign 1004, and a second (in FIG. 1 the left) axial end position is denoted with reference sign 1004′. Actuating element 1004 has at least one metallic component in which eddy currents can be induced, in particular when applied with an alternating magnetic field. In some embodiments, actuating element 1004 can be made entirely of metal. In other embodiments, actuating element 1004 can also have a non-metallic base body and, for example, a metallic layer, in particular a metallization of a surface of the base body. Alternatively or in addition, a metallic body can be arranged on the base body of actuating element 1004. With other embodiments, it is also conceivable to design the actuating element non-metallic, but electrically conductive. With other preferred embodiments, actuating element 1004 is movably attached to housing 1002 in the manner described above, e.g. detachably connectable or (non-destructively) non-detachably connectable to the same.

With other embodiments, it is also conceivable not to attach or at least not to permanently attach actuating element 1004 to housing 1002, but to provide it as a separate component and, if necessary, to approach it to housing 1002 in order to enable the evaluation described below.

Device 1000 also comprises an inductive sensor 1100 having a sensor coil 1112 for detecting a position and/or movement of actuating element 1004, which—like sensor coil 1112—is preferably located inside housing 1002. In contrast, actuating element 1004 is usually arranged outside housing 1002, regardless of whether it is attached to housing 1002 or not.

FIG. 4 shows a simplified block diagram of inductive sensor 1100. Inductive sensor 1100 comprises: a first measuring resonant circuit 1110 comprising sensor coil 1112 (FIG. 1), in which a first measuring oscillation MS can be generated, and an oscillation generator 1130, which is configured to generate an excitation oscillation ES and to apply the excitation oscillation ES at least temporarily to first measuring resonant circuit 1110.

Furthermore, the device comprises an evaluation device 1200 which is configured to determine, depending on the first measuring oscillation MS, movement information BI (FIG. 4) characterizing the position and/or movement of actuating element 1004 (FIG. 1). With preferred embodiments, the functionality of evaluation device 1200 can be integrated in inductive sensor 1100. With other embodiments, it is also conceivable to implement the functionality of evaluation device 1200 at least partially outside inductive sensor 1100. For example, in some embodiments, device 1000 (FIG. 1) can comprise an optional control unit 1010 which controls the operation of device 1000 and of one or more optional functional units 1300, 1302. With these embodiments, control unit 1010 can be configured to implement at least a part of the functionality of evaluation device 1200. With preferred embodiments, the determined movement information BI can be used advantageously to control the operation of the device 1000 and/or at least one component, for example the functional unit 1300 (FIG. 4).

FIG. 5A shows a simplified flowchart of a method according to an embodiment. In a first step 100, oscillation generator 1130 (FIG. 4) generates an excitation oscillation ES. The excitation oscillation ES can be, for example, a decaying oscillation, as schematically indicated in FIG. 7A by reference sign 11.

In step 110 (FIG. 5A), oscillation generator 1130 (FIG. 4) applies the excitation oscillation ES to first measuring resonant circuit 1110 such that a swelling and then decaying first measuring oscillation 7, see FIG. 7B, is produced in first measuring resonant circuit 1110. In step 120 (FIG. 5A), evaluation device 1200 (FIG. 4) determines movement information BI characterizing the position and/or movement of actuating element 1004 (FIG. 1) depending on the first measuring oscillation MS.

Optionally, in step 130, an operation of device 1000 or of at least one of its functional components 1300, 1302, for example, can advantageously be controlled depending on movement information BI. For example, it is conceivable that functional component 1300 is activated when actuating element 1004 approaches sensor coil 1112, which can be determined according to the principle of the invention using inductive sensor 1100. This can be done, for example, under the control of control unit 1010. In order to achieve a particularly energy-efficient configuration, movement information BI provided by inductive sensor 1100 can be used, for example, to switch control unit 1010 from an energy-saving state to an operating state in which the activation of component 1300 can be carried out.

In general, the excitation oscillation ES and/or a measuring oscillation MS of first measuring resonant circuit 1110 can be characterized, for example, by a time-varying electric voltage and/or a time-varying electric current. In some embodiments, evaluation device 1200 can evaluate, for example, an electric voltage at sensor coil 1112 and/or an electric current through sensor coil 1112 to determine movement information BI.

A particular advantage of the embodiments that involve a swelling and then decaying measuring oscillation 7 (FIG. 7B) in measuring resonant circuit 1110 (FIG. 4) is that a signal maximum (e.g. a maximum voltage) of the swelling and then decaying oscillation is, in comparison to a merely decaying oscillation, for example, considerably stronger dependent on an interaction of sensor coil 1112 (FIG. 1) with actuating element 1004 or its at least one metallic component, which results in a greater sensitivity of the proposed measuring principle than with conventional inductive methods, and which enables a more precise determination of movement information BI.

With preferred embodiments, an interaction of actuating element 1004 (FIG. 1) (or its metallic or electrically conductive component, respectively) with the sensor coil 1112, which can be evaluated by evaluation device 1200, is such that an alternating magnetic field caused by the measuring oscillation MS (FIG. 4) in the region of sensor coil 1112 (FIG. 1) induces eddy currents in actuating element 1004 (or its metallic or electrically conductive component). This can, for example, cause an attenuation of the first measuring oscillation. Depending on the arrangement of actuating element 1004 in relation to sensor coil 1112, this interaction can be stronger or weaker, which can be evaluated by evaluation device 1200. In particular, both a position of the actuating element and movements of the actuating element can be detected. For example, in some embodiments, a comparatively weak attenuation of the first measuring oscillation MS (FIG. 4) by actuating element 1004 results when it is arranged in its right axial end position in FIG. 1, i.e. away from sensor coil 1112, and a comparatively strong attenuation of the first measuring oscillation MS (FIG. 4) by actuating element 1004 results when it is arranged in its left axial end position in FIG. 1, i.e. in the region of sensor coil 1112, see reference sign 1004′.

With other embodiments, it is also conceivable that an approach of actuating element 1004 or of its metallic component to sensor coil 1112 or a withdrawal from sensor coil 1112 affects the resonant frequency of first measuring resonant circuit 1110, so that instead of the above-mentioned attenuation, also an amplification of the first measuring oscillation MS can result when actuating element 1004 approaches first sensor coil 1112.

FIG. 2 schematically shows a block diagram of an electronic device 1000a according to a second embodiment. In contrast to the configuration 1000 as shown in FIG. 1, configuration 1000a as shown in FIG. 2 has actuator 1004a mounted rotatably around a fulcrum DP with respect to the housing 1002, so that it can be moved, for example, between at least two different angular positions 1004a, 1004a′ in the sense of a rotation, see the double arrow a2. For the determination of movement information BI, the above with reference to FIGS. 1, 4, 5A applies accordingly.

FIG. 3 schematically shows a block diagram of an electronic device 1000b according to a third embodiment. Actuating element 1004b is essentially sleeve-shaped and is arranged coaxially around housing 1002 of device 1000b and is mounted on the same such that it can be moved axially back and forth, see double arrow a3. An axial end position of actuating element 1004b in the region of sensor coil 1112 is indicated by reference sign 1004b′. For the determination of movement information BI the above with reference to FIGS. 1, 4, 5A applies accordingly.

In other embodiments, oscillation generator 1130 (FIG. 4) is configured to generate a plurality of temporally consecutive excitation oscillations ES and to apply the plurality of excitation oscillations to the first measuring resonant circuit, resulting in particular in a plurality of measuring oscillations corresponding to the number of the plurality of temporally consecutive excitation oscillations. This enables a non-vanishing “measuring rate”, i.e. the repeated determination of movement information BI.

In other embodiments, oscillation generator 1130 (FIG. 4) is configured to periodically generate the plurality of excitation oscillations ES with a first clock frequency and to apply the periodically generated excitation oscillations to first measuring resonant circuit MS. In further embodiments, the first clock frequency is between about 0.5 Hertz and about 800 Hertz, preferably between about 2 Hertz and about 100 Hertz, and more preferably between about 5 Hertz and about 20 Hertz. The first clock frequency can, for example, define the above-mentioned measuring rate, provided that one movement information BI is determined for each measuring oscillation, for example. The first clock frequency must be distinguished from the natural frequency of the oscillation generator, which is usually much higher than the first clock frequency. For example, the excitation oscillation 11 shown in FIG. 7A comprises a large number of complete (e.g. sinusoidal) oscillation periods with the natural frequency of the oscillation generator. The entirety of this plurality of oscillation periods with the natural frequency of the oscillation generator shown in FIG. 7A is herein referred to as “one excitation oscillation” ES, 11 (the same applies to measuring oscillation 7 according to FIG. 7B). In contrast, the first clock frequency indicates how often per time unit such an excitation oscillation ES, 11 is generated. If, for example, the first clock frequency is selected to be 10 Hertz, then a total of 10 excitation oscillations 11 of the type shown in FIG. 7A are generated within one second.

For manually operated devices, for example, a measuring rate of about 10 Hertz can be useful, because then, for example, a corresponding movement information BI can be determined ten times per second, which ensures a sufficiently fast response for many applications, e.g. for the detection of a change in position of actuating element 1004, 1004a, 1004b.

With other embodiments, it is also conceivable to provide a device that is not or not only manually operable or operable by a person, but can be used, for example, within a (partially) automated system such as a manufacturing system with robots. With these embodiments, inductive sensor 1100 can also be used, for example, to detect the position and/or movement of a metallic and/or electrically conductive component of this system, e.g. to form an inductive proximity sensor.

In other embodiments, oscillation generator 1130 (FIG. 4) is configured to apply the excitation oscillation ES to first measuring resonant circuit 1110 such that the first measuring oscillation MS is a swelling and subsequently decaying oscillation. This results in a particularly sensitive evaluation, as already mentioned above.

In other embodiments, first measuring resonant circuit 1110 can be brought into resonance with the excitation oscillation ES, in particular to generate a swelling and subsequently decaying measuring oscillation MS .

FIG. 5B shows a simplified flowchart of a method according to another embodiment. Step 150 represents a periodic generation of a plurality of decaying excitation oscillations, e.g. with a waveform 11 according to FIG. 7A. Step 160 represents the application of first measuring resonant circuit 1110 with a respective excitation oscillation, resulting in corresponding measuring oscillations, e.g. with a waveform 7 according to FIG. 7B. Although steps 150, 160 are described herein as being carried out one after the other for reasons of clarity, it is clear that the generation of the plurality of excitation oscillations and the application of the respective excitation oscillations to the measuring resonant circuit is carried out such that after the generation of a respective excitation oscillation, this is first applied to the measuring resonant circuit in order to excite the corresponding measuring oscillation, and that only then the next excitation oscillation is generated.

In the optional step 170 in FIG. 5B, evaluation device 1200 (FIG. 4) determines movement information BI depending on one or more of the measuring oscillations previously generated by steps 150, 160. In the further optional step 180, a control of the operation of the device 1000 (FIG. 1) or of at least one of its components 1010, 1300, 1302 can be performed depending on the previously determined movement information BI.

In further embodiments, first measuring resonant circuit 1110 (FIG. 4) is a first LC oscillator having a first resonant frequency, wherein sensor coil 1112 (FIG. 1) is an inductive element of the first LC oscillator, and wherein a capacitive element of the first LC oscillator is connected in parallel with sensor coil 1112. In this case, in a manner known per se, the first resonant frequency, which is the natural resonant frequency of the first LC oscillator, results from the inductance of sensor coil 1112 and the capacitance of the capacitive element.

In other embodiments, oscillation generator 1130 is configured to generate the excitation oscillation ES with a second frequency, wherein the second frequency is between about 60 percent and about 140 percent of the first resonant frequency of the first LC oscillator, particularly preferably between about 80 percent and about 120 percent, and more preferably between about 95 percent and about 105 percent of the first resonant frequency. Thus, a preferred swelling and decaying signal shape for the measuring oscillation can be obtained in a particularly efficient manner.

In other embodiments, oscillation generator 1130 (FIG. 4) comprises a second LC oscillator (FIG. 4) and a clock generator which is configured to apply the second LC oscillator with a first clock signal or a signal derived from the first clock signal (for example an amplified first clock signal) which has the first clock frequency and a pre-determinable duty cycle. In further embodiments the pre-determinable duty cycle is between about 100 nanoseconds and about 1000 milliseconds, in particular between about 500 nanoseconds and about 10 microseconds, and more preferably about one microsecond.

In other embodiments, first measuring resonant circuit 1110 is inductively coupled with oscillation generator 1130. In some embodiments, this can be achieved, for example, by an inductive element of the second LC oscillator being designed and arranged with respect to the sensor coil 1112 such that the magnetic flux generated by it at least partially passes also through sensor coil 1112 in accordance with the desired degree of coupling. For example, both the sensor coil 1112 and the inductive element of the second LC oscillator can be designed as cylindrical coils for this purpose.

With other embodiments, it is also conceivable that a magnetic or inductive coupling between oscillation generator 1130 and first measuring resonant circuit 1110 is undesirable. In this case, for example, the inductive element of the second LC oscillator can be designed such that the interaction of its magnetic field with sensor coil 1112 is as low as possible. In this case, for example, the inductive element of the second LC oscillator can be designed as a micro-inductance, e.g. in the form of an SMD component.

In other embodiments, first measuring resonant circuit 1110 is capacitively coupled to oscillation generator 1130, e.g. via a coupling element which preferably consists of an electric serial connection of a coupling resistor and a coupling capacitor. This allows to precisely adjust the coupling impedance.

With reference to FIG. 6, a possible circuitry implementation 1 of the inductive sensor according to further embodiments is described below.

In a first region B1 of the circuit diagram, an oscillation generator 13 is provided, which for example has the functionality of oscillation generator 1130 described above with reference to FIG. 4. In a second region B2 of the circuit diagram, a first measuring resonant circuit 15, for example comparable to first measuring resonant circuit 1110 described above with reference to FIG. 4, is provided, and in a third region B3, circuit components are provided which, for example, implement the functionality of evaluation device 1200 described above with reference to FIG. 4.

First measuring resonant circuit 15 as shown in FIG. 6 comprises a parallel connection of a sensor coil 3, corresponding for example to sensor coil 1112 described above with reference to FIG. 1, and a capacitor 53, thus forming a first LC oscillator. Together with sensor coil 3, capacitor 53 defines a natural resonant frequency of the first LC oscillator or measuring resonant circuit and can therefore also be described as a resonant capacitor. In the region of sensor coil 3, a metallic (and/or electrically conductive) component 2 is schematically shown, the position and/or movement of which can be determined by applying the principle of the embodiments. Metallic component 2 is, for example, part of actuating element 1004, 1004a, 1004b according to FIG. 1, 2, 3, or forms this actuating element.

First measuring resonant circuit 15 is capacitively (or capacitively and resistively) coupled to oscillation generator 13 via a coupling impedance, presently formed by a serial connection of a resistor 55 and a capacitor 57. Oscillation generator 13 is configured to apply, preferably periodically, excitation oscillations 11 to first measuring resonant circuit 15, whereby corresponding measuring oscillations 7 are excited in first measuring resonant circuit 15. For example, for this purpose, first measuring resonant circuit 15 can be periodically applied with current by the oscillation generator 13 via coupling impedance 55, 57, wherein a coupling factor can be precisely adjusted by the selection of the resistance value of resistor 55 and/or the capacitance of capacitor 57.

To generate the excitation oscillation(s) 11, oscillation generator 13 comprises an excitation resonant circuit with an inductive element, in particular a coil 59, and a capacitor 61, which form a second LC oscillator. Oscillation generator 13 also comprises a clock generator 63. By means of clock generator 63, a first clock signal TS1, also indicated in FIG. 6 by square pulse 65 (“clock”), can be generated. Clock 65, for example, has a pulse duration or duty cycle of one microsecond (μs) at a first clock frequency of 10 Hertz. This corresponds to a period duration of 100 milliseconds (ms), whereby the duty cycle indicates that for a total of 1 microsecond the first clock signal TS1 has a value of e.g. logic one (or another non-vanishing amplitude value, which also results e.g. from a value of the operating voltage V1 in relation to the ground potential GND of e.g. 3 volts), and for the remaining period duration a value of zero. This comparatively small duty cycle of 1 μs/100 ms=1:100000 enables a particularly energy-efficient operation of sensor 1.

Inductive sensor 1 shown in FIG. 6 is applied with current by the first clock signal TS1 during the duty cycle and is essentially currentless during the clock pauses. The preferred clock generator is an ultra-low power clock generator module having a current consumption of less than about 30 nanoamperes (nA) at an operating voltage of 3 V. This allows to provide a very energy-efficient inductive sensor.

With other embodiments, the values for the first clock frequency and/or the duty cycle itself can be selected as desired. If, for example, an industrial proximity sensor requires the fastest possible detection of metallic component 2 at sensor coil 3, the generation of the next excitation oscillation 11 can be preferably started immediately after a first excitation oscillation 11 (FIG. 7A) has decayed below a pre-settable first threshold value, preferably about zero.

In a preferred embodiment, the first clock signal TS1 controls an electric switching element 67, for example a field effect transistor, which is connected in series with second LC oscillator 59, 61.

With preferred embodiments, clock generator 63 or the entire sensor 1 can be supplied with operating voltage V1 from an electric energy source not shown in FIG. 6, which is provided, for example, by a battery and/or a solar cell and/or a device for energy harvesting (taking energy from the environment and converting it into electric energy if necessary). Sensor 1 can preferably use an electric energy supply of its target system, here e.g. the device 1000 (FIG. 1), for example a battery (not shown), which also supplies control unit 1010 and/or at least one functional unit 1300, 1302 with electric energy.

During a duty cycle of clock 65, electric switching element 67 is switched on, e.g. a drain-source route of the field-effect transistor has low impedance, and as a result a DC voltage V1 is applied to the second LC oscillator or excitation circuit 59, 61 of oscillation generator 13. This causes a magnetic field to be built up in coil 59. During the clock pauses, electric switching element 67 opens and the excitation resonant circuit of oscillation generator 13 gets into a decaying oscillation, the excitation oscillation 11, see FIG. 7A. In the clock pauses of clock 65, first measuring resonant circuit 15 is thus energized via coupling impedance 55, 57 with the decaying excitation oscillation 11. This excites it to a first measuring oscillation 7, see FIG. 7B, and in the case of preferred embodiments, it gets into resonance in particular with the excitation oscillation 11, wherein the first measuring oscillation 7 preferably is obtained as a swelling and then decaying measuring oscillation 7.

The measuring oscillation 7 depends via sensor coil 3 on the position and/or movement of metallic component 2, for example on a presence or absence of component 2 in the region of sensor coil 3 and/or an approach or withdrawal of component 2. To detect the position and/or movement of component 2 or to evaluate the first measuring oscillation 7, a circuit group is assigned to first measuring resonant circuit 15 (FIG. 7), which is shown mainly in the third region B3 according to FIG. 6.

This circuit group has a maximum value memory 27 as well as a preset value generating device VG which is e.g. designed as a voltage divider with a first preset resistor 69 and a second preset resistor 71. Maximum value memory 27 stores a maximum value of an amplitude value 17 of the first measuring oscillation 7 and provides it at its output as memory value 25. Maximum value memory 27 is followed by a time delay element 73. Time delay element 73 delays the memory value 25 present at the output of maximum value memory 27 preferably by a period PD (FIG. 8) of the first clock signal TS1, whereby a delayed memory value 25′ is obtained. Alternatively, the delay is obtained by means of an integrating filter. In one configuration, time delay element 73 comprises a low-pass filter.

A preset output 75 of preset value generating device VG and an output of time delay element 73 are connected upstream of a comparator 77. The delayed memory value 25′ (i.e. the first maximum amplitude value 17 delayed by one clock pulse) of a first clock cycle and a second amplitude value 21 of a second clock cycle being one clock pulse later are thus applied to comparator 77. The delayed memory value 25′ is compared with the second amplitude value 21 by means of comparator 77. In addition, the second amplitude value 21 is reduced by means of the voltage divider VG by a corresponding threshold 29 (FIG. 7B) before it acts on comparator 77.

Maximum value memory 27, time delay element 73 as well as comparator 77 can form a differentiating element in some embodiments, which differentiates the first measuring oscillation 7 over one period length of clock 65. Comparator 77 generates a set signal 79 as an output signal if preset output 75 is greater than the delayed memory value 25′.

With preferred embodiments, the differential formed exemplarily by means of comparator 77, time delay element 73 and maximum value memory 27 is thus compared with the threshold 29 via preset resistors 69 and 71, wherein comparator 77 generates the positive set signal 79 when the differential of the first measuring oscillation 7 exceeds the threshold 29. This can be the case with some embodiments if, for example, metallic component 2 is withdrawn from sensor coil 3 and thus causes no or only a lower attenuation of the signal in sensor coil 3.

With other preferred embodiments, a flip-flop element 81 is connected downstream of comparator 77, in particular a set input 81a for setting the flip-flop element 81.

Moreover, a reset input 81b of flip-flop element 81 is connected downstream of clock generator 63. In this way, flip-flop element 81 is reset at each clock 65, i.e. when oscillation generator 13 is applied with current. This ensures that flip-flop element 81 is reset at the clock cycle of the disconnection of excitation resonant circuit 13 from the electric energy source not shown in detail (at the falling edge of the first clock signal TS1 or of clock 65), i.e. when the excitation oscillation 11 begins. If the withdrawal and/or absence of metallic component 2 from sensor coil 3 is detected by comparator 77 and the latter generates the set signal 79, as described above, flip-flop element 81 is being set.

With other embodiments, an optional low-pass filter 83 can be connected downstream of flip-flop element 81 to bridge time periods after resetting flip-flop element 81 by clock 65 and setting again by set signal 79. A non-vanishing output signal 83′ of low-pass filter 83 is thus present, for example, when the withdrawal of component 2 has been detected. This output signal 83′ can be used with other preferred embodiments for switching and/or controlling at least one component of the target system of inductive sensor 1, e.g. a device 1000 as shown in FIG. 1. For example, the output signal 83′ can be fed to control unit 1010 of device 1000, which evaluates it, for example to determine movement information BI (FIG. 4), and depending on this, to control an operating state and/or a change of an operating state of function component 1300 of device 1000, for example. With other embodiments, the output signal 83′ can be used directly as movement information BI.

In order to achieve a particularly energy-efficient configuration, with other embodiments, the output signal 83′ can be used, for example, to switch control unit 1010 (FIG. 1) of device 1000 from an energy-saving state to an operating state in which, for example, activation of component 1300 can be carried out. This can be done, for example, by connecting the output signal 83′ to an input of control unit 1010, which may be a microcontroller or the like, such that the output signal 83′ triggers an interrupt request, which transfers the microcontroller from the energy-saving mode to an active operation mode.

With other preferred embodiments, depending on the design of the threshold values and/or resonant frequencies of first measuring resonant circuit 15 or its first LC oscillator and/or oscillation generator 13 or its second LC oscillator, the approach or withdrawal of metallic component 2 can be detected, for example.

With other preferred embodiments, maximum value memory 27 (FIG. 6) is also connected downstream of clock generator 63, so that an operating state of maximum value memory 27 can be controlled depending on the first clock signal TS1. For example, in each individual clock cycle 65, maximum value memory 27 is preferably reduced in the whole or in part by a value. Alternatively, it is possible to dispense with maximum value memory 27, preset resistors 69 and 71 as well as time delay element 73 and instead to provide a fixed threshold value, i.e. to check only the fixed or pre-settable threshold value and to switch depending on it.

With other embodiments, it is conceivable that, for example, a single excitation oscillation 11 (FIG. 7A) is generated for a measuring process, which accordingly causes a single first measuring oscillation 7 or MS1 (FIG. 7B) in first measuring resonant circuit 15. When calibrating the inductive sensor 1, e.g. by means of preceding reference measurements which involve an arrangement of metallic component 2 in various positions relative to sensor coil 3 and a corresponding evaluation of, for example, at least one amplitude value of the first measuring oscillation per position, already with the evaluation of a single measuring oscillation a movement information BI can advantageously be determined which describes a position of metallic component 2 relative to sensor coil 3. With these embodiments, a comparison of several, for example directly consecutive, measuring oscillations of the first measuring resonant circuit is therefore not necessary. With other preferred embodiments, however, as described above with reference to FIG. 6, a plurality of measuring oscillations are excited by corresponding excitation oscillations and the movement information is determined depending on the plurality of measuring oscillations.

FIG. 7 shows different signal courses of the excitation oscillation 11 as well as the first measuring oscillation 7. In a diagram A (FIG. 7A) of FIG. 7, the decay of the excitation oscillation 11 is clearly visible, which occurs after disconnecting excitation oscillation circuit 59, 61 (FIG. 6) from the electric power supply V1, GND.

In a diagram B (FIG. 7B) of FIG. 7, two signal courses MS1, MS2 of measuring oscillations 7 as a result of the energization of first measuring resonant circuit 15 (FIG. 6) by means of the excitation oscillation 11 shown in FIG. 7A are each plotted in a comparison. A solid line MS1 represents a first measuring oscillation of a first clock cycle (excited by an application with a first excitation oscillation 11 according to FIG. 7A), which has the first amplitude value 17, which is symbolized in FIG. 7 by a horizontal line.

A dotted line represents another one of the measuring oscillations 7 (excited by an application with a second excitation oscillation 11 as shown in FIG. 7A), which has the second amplitude value 21 at a second clock cycle, which is also symbolized in FIG. 7B by a horizontal line. The amplitude values 17 and 21 are each the maximum values of the measuring oscillations MS1, MS2 which are swelling and then decaying with each clock cycle.

The situation MS2 shown in FIG. 7B as a dotted line results, for example, when metallic component 2 (FIG. 6) is withdrawn from sensor coil 3, which is thus less attenuated. It can be seen that therefore, in a second clock cycle the second amplitude value 21 is higher than the first amplitude value 17 of the first clock cycle. If the second amplitude value 21 exceeds threshold 29 (FIG. 7B) specified by means of resistors 69 and 71 shown in FIG. 6 and/or by the at least partial reduction of the memory value 25, comparator 77 generates the set signal 79 for setting flip-flop element 81.

FIG. 8 illustrates different signal courses A to F of different signals of inductive sensor 1 shown as an example in FIG. 6, when metallic component 2 is present in the region of sensor coil 3. FIG. 9 shows the signal courses of FIG. 8, but when metallic component 2 is withdrawn from sensor coil 3 and when metallic component 2 approaches sensor coil 3 again.

In a diagram A of FIGS. 8 and 9, a total of four periods of each of the first clock signal TS1 (FIG. 6) and the clock 65 are shown. In FIG. 8A, a period duration is denoted with the reference sign PD and a duty cycle is denoted with the reference sign TL. The ratio between the duty cycle TL and the pauses P in between (corresponding to the period duration PD minus the duty cycle TL) or the period duration PD, respectively, is preferably chosen very small for a power-saving system according to preferred embodiments, see above, for example with values of about 1:10000 and smaller, preferably about 1:100000, and it is not shown to scale in FIGS. 8, 9 for the sake of clarity. In a diagram B of FIGS. 8 and 9, the swelling and decay of the measuring oscillation 7 is shown, each schematized. In a diagram C of FIGS. 8 and 9, the set signal 79 provided at the output of comparator 77 and applied to the set input 81a of flip-flop element 81 is shown. In a diagram D of FIGS. 8 and 9, respectively, a signal is shown which is applied to the reset input 81b of flip-flop element 81 and which corresponds to the first clock signal TS1 or clock 65. In a diagram E of FIGS. 8 and 9, respectively, the memory state (output signal) of flip-flop element 81 is shown. In a diagram F of FIGS. 8 and 9, respectively, a temporal course of an output signal of time delay element 73 is shown, i.e. the temporally delayed memory value 25′ which is fed to comparator 77.

As can be seen in FIG. 8D, flip-flop element 81 is reset for each completed clock 65 and consistently shows the reset memory state, as shown in FIG. 8E. As can be seen in FIG. 8B, after each end (falling edge) of the respective clock 65, one of the measuring oscillations 7 begins, which, due to the presence of metallic component 2, each have identical maximum amplitude values, which is symbolized in FIG. 8B by a dashed horizontal line 21′. These maximum amplitude values 21′ preferably correspond to the respective first and second amplitude values 17, 21, see also FIG. 7B. Since the measuring oscillation 7 swells and then decays again, the respective maximum amplitude value only occurs after a certain number of oscillation periods of the respective measuring oscillation, in particular directly at the transition from the swelling to the decay. According to the principle of the present embodiments, the maximum of the respectively occurring amplitudes can be determined or stored with little effort and is already affected by the position or movement of metallic component 2 during the swelling oscillations. Since in some embodiments the influence is added up over time and is measured at a signal maximum occurring with a time delay, a sensitivity and a quality of the measurement can be further improved compared to conventional approaches (e.g. just considering a decaying oscillation).

In diagram F of FIG. 8, the temporal course of the output signal of time delay element 73, the time-delayed memory value 25′, is shown as steady state. This is the case, for example, if metallic component 2 does not move relative to sensor coil 3 (FIG. 6) for a time period exceeding the time delay of time delay element 73.

In comparison to this, FIG. 9 shows that an amplitude of the second measuring oscillation 7′ shown in FIG. 9B briefly exceeds threshold 29, for example due to a movement of metallic component 2 relative to sensor coil 3 (FIG. 6). This causes a non-vanishing output signal, namely the set signal 79, at the output of comparator 77 and thus also at set input 81a of flip-flop element 81, as shown in diagram C of FIG. 9. As can be seen in diagram E of FIG. 9, this sets flip-flop element 81. Flip-flop element 81 remains set until the next clock 65, which causes a reset.

After a third clock pulse shown in FIG. 9, there is another increase in the amplitude of the third measuring oscillation 7″, which, compared to the second measuring oscillation 7″ shown in FIG. 9B, exceeds the threshold 29 even further. The set signal 79 is generated again, which sets flip-flop element 81 for another period of clock 65. After a fourth period of clock 65, metallic component 2 has again approached sensor coil 3

(FIG. 6). It can be seen that as a result, the threshold 29 is not exceeded by the fourth measuring oscillation 7″' and therefore flip-flop element 81 remains reset. It can also be seen that the time-delayed memory value 25′ slowly decreases again.

Generally, other methods of signal evaluation are also possible with other embodiments, for example using fixed or dynamically re-adjusted thresholds.

As can be seen in FIGS. 8 and 9, in the embodiment described, a measuring oscillation 7′ or the first amplitude value 17 of a first clock cycle 19 is compared with a subsequent measuring oscillation 7″ or a second amplitude value 21 of a second clock cycle 23. This is preferably carried out cyclically once per clock cycle, wherein in particular the respective amplitude value of a current clock cycle is compared with the corresponding amplitude value (preferably the respective maximum or minimum amplitude value) of the clock cycle preceding this clock cycle.

The presence of metallic component 2 in the region of sensor coil 3 (FIG. 6) causes in some embodiments an attenuation of the measuring oscillation 7 in sensor coil 3, in particular due to eddy currents induced in component 2 by measuring oscillation 7 or the associated alternating magnetic field, and thus prevents a setting of flip-flop element 81, as shown in FIG. 8C.

With other embodiments, it is also possible that metallic component 2 affects a natural resonant frequency of the first LC-oscillator or of the first measuring resonant circuit 15 such that it is closer to a frequency of the excitation oscillation 11, and therefore a possible resonance of the first LC-oscillator of first measuring resonant circuit 15 with the second LC-oscillator of oscillation generator 13 is more amplified than attenuated by metallic component 2. As a result, the presence of metallic component 2 can cause an increase in the amplitude values 17, 21 and thus sets flip-flop element 81.

FIG. 10 shows schematically a circuit diagram of an inductive sensor 1a according to another embodiment, which also allows the detection of a position and/or movement of a metallic component 2. Sensor 1a comprises a first sensor coil 3 as well as a further sensor coil 5, wherein metallic component 2 for the above-mentioned detection is moved towards at least one of the two sensor coils 3 or 5, for example.

In the following, only the differences to inductive sensor 1 shown in FIG. 6 will be discussed, and apart from that, reference is made to FIG. 6 and the corresponding description. In contrast to the illustration in FIG. 6, inductive sensor 1a in FIG. 10 comprises the first measuring resonant circuit 15 as well as a further (second) measuring resonant circuit 16. Both measuring resonant circuits 15, 16 are each formed by an LC oscillator with elements 3, 53 and 5, 53′ respectively. The measuring resonant circuits 15 and 16 are connected via a respective coupling impedance 55, 57 and 55′, 57 to excitation resonant circuit 59, 61 of oscillation generator 13, so that both measuring resonant circuits 15 and 16 can be jointly applied with a corresponding excitation oscillation 11 by oscillation generator 13. Accordingly, a first measuring oscillation 7 is formed in first measuring resonant circuit 15 and a secondary measuring oscillation 9 in second measuring resonant circuit 16.

First measuring resonant circuit 15 generates a first output signal 33 which depends on the position and/or movement of metallic component 2. In an analog manner, second measuring resonant circuit 16 generates a second output signal 35. Both output signals 33, 35 are fed to a differential amplifier 43 which generates a differential signal 31 from them. Due to the forming of a difference, the differential signal 31 is basically robust against disturbances acting on sensor coil 3 as well as the other sensor coil 5 of second measuring resonant circuit 16.

Both sensor coils 3 and 5 can preferably be oriented in the same way and in particular be arranged in front of or next to each other. A distance between the two sensor coils 3, 5 can preferably be selected for some embodiments such that, if applicable, metallic component 2 only acts on one of the two measuring resonant circuits 15, 16 without significantly affecting the other.

Since sensor coils 3 and 5 are at least a small distance apart due to their design, disturbances can, however, lead to a slightly changed differential signal 31 in some embodiments. In order to also eliminate this effect, with some embodiments, maximum value memory 27 and an evaluation circuit 39 connected downstream of it are designed such that differential signal 31 in a first time window 49, which is shown in FIG. 12, is compared with differential signal 31 in a second time window 51, which is also shown in FIG. 12. Maximum value memory 27 and evaluation circuit 39 are time-controlled for this purpose, for example by means of clock generator 63. This allows to save electric energy.

The exact function and possible configurations of maximum value memory 27 shown in FIG. 10 will be explained in more detail below with reference to FIG. 11. Maximum value memory 27 comprises a first partial memory 85, which is connected during the first time window 49 by means of an electric switching element to the output of differential amplifier 43, i.e. differential signal 31. Analog to this, a second partial memory 87 is also connected during the second time window 51 by means of an electric switching element to the output of differential amplifier 43, i.e. differential signal 31. Comparator 77 compares the memory outputs of first partial memory 85 and second partial memory 87, i.e. the respective differential signal 31 of the first time window 49 and the second time window 51 with each other. If a differential threshold merely indicated in FIG. 11 by means of the reference sign 37 is exceeded, comparator 77 generates the set signal 79 to set the flip-flop element 81. Partial memories 85 and 87 can preferably be supplied with electric energy by clock generator 63, i.e. they are essentially currentless in the pauses of clock 65 or in measurement pauses specified by the same, respectively. This allows to further reduce the power consumption.

FIG. 12 shows in illustrations A to D different courses of the differential signal 31 of inductive sensor 1a depicted in FIGS. 10 and 11.

Clock 65 is shown in FIG. 12A. FIG. 12B shows that during clock 65 there is no excitation oscillation 11 applied to measuring resonant circuits 15 and 16. As soon as clock 65 ends, and thus, the excitation resonant circuit is no longer applied with current, the decaying excitation oscillation 11 occurs. According to the illustration in FIG. 12C, the differential signal 31 from the measuring oscillation 7 and a further measuring oscillation 9 of the further measuring resonant circuit 16, e.g. when metallic component 2 approaches, is shown as a result of the excitation by means of the excitation oscillation 11. The approach of metallic component 2 leads to a detuning of at least one of the measuring resonant circuits 15 and/or 16, and thus to a swelling and then decaying differential signal 31, as shown with the course of FIG. 12C.

In FIG. 12D, it can be seen that without an approximation of metallic component 2, the differential signal 31 has a substantially constant fundamental oscillation. This can be caused by an electromagnetic disturbance, for example, acting on inductive sensor 1a.

In principle, the disturbance can be reduced by forming the differential signal 31, but not completely due to a possibly different distance of sensor coils 3 and 5 from an disturbance signal source. In order to eliminate this remaining disturbance signal, with further embodiments, the differential signal 31 is considered in the first time window 49, which is symbolized by two vertical lines in FIG. 12, in comparison to a course during the second time window 51, which is also symbolized by two vertical lines in FIG. 12. As can be derived from FIG. 12C, comparator 77 generates the set signal 79 only if a maximum value of an amplitude of the difference signal 31 of the second time window 51 exceeds a maximum value of the amplitude of the difference signal 31 of the first time window 49 by the difference threshold 37.

With preferred embodiments, the first time window 49 corresponds in particular to the length of the clock 65, i.e. a duty cycle TL, see also FIG. 8. The second time window 51 comprises at least a part of the measuring oscillations 7 and 9 generated in the measuring resonant circuits 15, 16 by coupling, in particular resonance, with the excitation oscillation 11 and the differential signal 31 formed therefrom. The second time window 51 preferably follows directly after the first time window 49 and begins, for example, as soon as clock 65 ends or the excitation oscillation 11 begins.

With preferred embodiments, the first time window 49 for the first determination of the amplitude of the differential signal 31 can be arranged within a period of time when inductive element 59 is energized, or can coincide with the same. With other preferred embodiments, the second time window 51 for the second determination of the amplitude of the differential signal 31 is arranged in a region of a maximum amplitude, in particular the highest resonant oscillation, of the differential signal 31 and/or the measuring oscillations 15, 16, wherein the measurement takes place. If the first amplitude changes, for example due to a disturbance variable acting on sensor coil 3 and/or 5, this is detected and, with preferred embodiments, the threshold value for the second amplitude, i.e. for the actual measurement to detect metallic component 2, adjusts accordingly.

With other preferred embodiments, it is possible to transfer energy from oscillation generator 13 to measuring resonant circuit(s) 15 and/or 16 completely or at least partially via an inductive energy transfer path (not shown) instead of via capacitor 57 and/or resistor 55. If applicable, coils 3 and/or 5 can receive the energy directly.

With other embodiments, evaluation device 1200 (FIG. 4) is configured to compare at least two maximum or minimum amplitude values of different oscillation periods of (the same) measuring oscillation 7 (FIG. 7B) with each other. Thus, it is possible to determine, for example, a speed of the swelling and/or decay of the measuring oscillation 7, from which movement information BI can be derived.

With other embodiments, evaluation device 1200 is configured to compare a maximum or minimum amplitude value of a first measuring oscillation 7′ (FIG. 9B) of a plurality of measuring oscillations 7′, 7″, . . . with a corresponding maximum or minimum amplitude value of at least one second measuring oscillation 7″ of the plurality of measuring oscillations, wherein preferably the second measuring oscillation follows the first measuring oscillation, in particular follows directly the first measuring oscillation (i.e. without a further measuring oscillation occurring between the first and second measuring oscillations).

FIG. 13 shows a simplified block diagram of an electronic device 1000c according to another embodiment. The device 1000c comprises a functional component 1300, which in this case is a measuring device 1300, which is configured to measure layer thicknesses, wherein measuring device 1300 is in particular configured to measure layer thicknesses of layers of lacquer and/or paint and/or rubber and/or or plastic on steel and/or iron and/or cast iron, and/or layers of lacquer and/or paint and/or rubber and/or or plastic on non-magnetic base materials such as aluminum, and/or copper and/or brass, for example.

Device 1000c is designed as a mobile device, in particular a hand-held device, and comprises a housing 1002 in which a control unit 1010 is provided for controlling an operation of device 1000c and in particular of measuring device 1300. An inductive sensor 1100 according to at least one of the embodiments described above with reference to FIGS. 1 to 12 or to a combination thereof is also arranged in housing 1002. For example, inductive sensor 1100 can have the construction as shown in FIG. 4, wherein a circuitry implementation of at least some of the components 1130, 1110, 1200 of inductive sensor 1100 can be realized, for example, similar or comparable to the embodiments described with reference to FIGS. 6 to 9 and/or comparable to the embodiments described with reference to FIGS. 10 to 12.

With preferred embodiments, device 1000c is configured to carry out or start at least one layer thickness measurement by measuring device 1300 depending on movement information BI which is determined by means of sensor 1100 and characterizes a position and/or movement of actuating element 1004c.

With other embodiments, housing 1002 has a substantially circular-cylindrical basic shape, wherein actuator 1004c has a substantially hollow-cylindrical basic shape and is coaxially surrounding a first axial end region 1002a of housing 1002. A compression spring is provided radially between housing 1002 and hollow-cylindrical actuating element 1004c, which is indicated only schematically by double arrow 1005 in FIG. 13. Furthermore, a stop 1002b is provided on housing 1002, which limits an axial movement of actuating element 1004c in FIG. 13 to the left. A corresponding stop for limiting the axial movement of actuating element 1004c in an opposite direction, i.e. to the right in FIG. 13, can also be provided as an option, but is not shown in FIG. 13 the sake of clarity.

To use the measuring device 1300, device 1000c can be grasped by a user and actuating element 1004c can be moved from its rest position shown in FIG. 13 against the spring force of compression spring 1005 in the direction of the first axial end region 1002a of housing 1002, i.e. to the left in FIG. 13. As a result, actuating element 1004c approaches first sensor coil 1112 of inductive sensor 1100 arranged within housing 1002, in particular in the first axial end region 1102a, whereby the interaction between actuating element 1004c or its metallic component (not shown in FIG. 13) and first sensor coil 1112, which has already been described several times above, changes in a way that can be detected by means of inductive sensor 1100. By means of evaluation device 1200 (FIG. 4), which in this case is integrated in inductive sensor 1100, for example, the movement information BI (FIG. 4) characterizing the position and/or movement of actuating element 1004c is generated and output, for example, directly to control unit 1010, which then activates measuring device 1300 to carry out one or more layer thickness measurements, for example by transferring it from an energy-saving state into an different operating state which allows coating thickness measurements.

With other embodiments, it may be provided that inductive sensor 1100 is used to determine when actuating element 1004c moves back into its rest position or when it is no longer positioned in the region of first sensor coil 1112. In this case, in further embodiments, control unit 1010 can put measuring device 1300 back into an energy-saving state, for example.

With further embodiments, device 1000c is configured to at least temporarily deactivate oscillation generator 1130 (FIG. 4), wherein in particular device 1000c is configured to at least temporarily deactivate oscillation generator 1130 depending on the movement information. This can be useful in those embodiments in which a signal 11, 7 generated by the inductive sensor according to the embodiments, in particular encompassing an alternating magnetic field, can possibly have a disturbing effect on the operation of measuring device 1300.

Due to the low duty cycle of the first clock signal TS1, which is preferred in some embodiments, and the comparatively long clock pauses coming along with the same, it is also possible in other embodiments to synchronize the measuring operation of measuring system 1300 with the operation of inductive sensor 1100 such that layer thickness measurements are carried out by measuring device 1300 within the clock pauses of the first clock signal TS1, in particular during those phases of the clock pause(s) during which an excitation oscillation 11 and preferably also a measuring oscillation 7 generated as a result thereof has decayed again below a pre-determinable threshold value. This results in an operation of measuring system 1300 that is largely unaffected by inductive sensor 1100.

With other embodiments, housing 1002 is hermetically sealed at least in the first axial end region 1002a.

Inductive sensors 1100, 1, 1a in accordance with the above-described embodiments can be advantageously used to provide a man-machine interface, for example using the above-described actuating element 1004, 1004a, 1004b, 1004c, wherein a metallic object or a metallic component or an at least partially metallic actuating element is arranged so as to be movable relative to the inductive sensor or at least the first sensor coil (translation and/or rotation or mixed forms thereof are possible).

The principle can also be used in particular for devices with partially or completely hermetically sealed (airtight) housings 1002, because the magnetic alternating fields associated with the measuring oscillation 7 can usually penetrate the housing wall sufficiently well, so that the proposed principle can be used reliably. In particular, no electrical, especially galvanic, connection between the actuating element and the inductive sensor is required.

Furthermore, the actuator or a metallic component attached to it does not need to be magnetic in order for the proposed principle to be useful. Rather, it is sufficient if eddy currents can be induced in the actuating element or at least in its metallic component by the alternating magnetic field of the sensor coil, i.e. electrical conductivity is present in the actuating element or at least in the metallic component assigned to it. Generally, the proposed principle can thus also be used to detect a non-metallic medium with regard to its position and/or movement relative to the sensor coil, as long as it is electrically conductive.

Further fields of application for the principle of the present embodiments are devices with switches or other actuating elements for explosion-proof rooms, diving applications, and in particular all other fields where actuation, in particular switching and/or operating, e.g. by means of magnets and Hall sensors, is not possible due to the possible presence of magnetic particles. Also applications are conceivable where a manipulation with haptic feedback, encapsulation and/or extremely low power consumption is desired, for example energy-autonomous, battery-powered and/or mobile devices.

The principle of the present embodiments allows advantageously the provision of devices 1000 with a very energy-efficient detection of a position and/or movement of at least one actuating element. Furthermore, with other embodiments, a plurality of actuating elements on one (same) device are conceivable, whose position and/or movement can be determined by one or possibly a plurality of inductive sensors of the type described.

As an alternative or in addition to a “binary” detection of positions (“actuating element is in the region of the sensor coil”/“actuating element is not in the region of the sensor coil”) or movement states (movement of the actuating element towards/away from the sensor coil), a determination of positions with a finer spatial resolution can be advantageously obtained. For this purpose, a plurality of threshold values can be provided for the principle described above e.g. with reference to FIG. 7B, the exceeding of which can be evaluated, e.g. by means of a plurality of comparators 77.

The term detection of a movement is to be interpreted broadly, in particular it can be understood to mean whether a distance between the actuating element and the at least one sensor coil is static and/or increases and/or decreases, whether the actuating element moves towards the coil and/or is present there and/or is moved away from it and/or is not present there. Alternatively or additionally, other evaluations are also possible, for example by means of fixed or dynamically readjusted thresholds for an absolute value of the amplitude. The amplitude values are preferably determined as respective maximum amplitude values, i.e. between swelling and decay of the respective measuring oscillation, for example when a signal maximum of the respective measuring oscillation occurs.

1. An electronic device comprising:
a housing;
an actuating element movable relative to the housing, the actuating element including at least one metallic component;
an inductive sensor for detecting at least one of a position and movement of the actuating element, the inductive sensor including:
a first measuring resonant circuit including a sensor coil, in which a first measuring oscillation is generatable. and
an oscillation generator configured to generate an excitation oscillation and to at least temporarily apply the excitation oscillation to the first measuring resonant circuit;
and evaluation device configured to determine, dependent on the first measuring oscillation, movement information characterizing the at least one of the position and movement of the actuating element; and
a measurement device configured to measure layer thickness, at least one of an operating state and a change of an operating state of the measurement device being controllable dependent upon the movement information.

2. The electronic device of claim 1, wherein the oscillation generator is configured to generate a plurality of temporally consecutive excitation oscillations and to apply the plurality of excitation oscillations to the first measuring resonant circuit, resulting a plurality of measuring oscillations corresponding to a number of the plurality of temporally consecutive excitation oscillations.

3. The electronic device of claim 2, wherein the oscillation generator is configured to periodically generate the plurality of excitation oscillations with a first clock frequency and to apply the periodically generated excitation oscillations to the first measuring resonant circuit.

4. The electronic device of claim 3, wherein the first clock frequency is between about 0.5 Hertz and about 800 Hertz.

5. The electronic device claim 1, wherein the oscillation generator is configured to apply the excitation oscillation to the first measuring resonant circuit such that the first measuring oscillation is a swelling and subsequently decaying oscillation.

6. The electronic device of claim 1, wherein the first measuring resonant circuit is configured to be brought into resonance with the excitation oscillation for generating a swelling and subsequently decaying measuring oscillation.

7. The electronic device of claim 1, wherein the first measuring resonant circuit is a first LC oscillator having a first resonant frequency, wherein the sensor coil is an inductive element of the first LC oscillator, and wherein a capacitive element of the first LC oscillator is connected in parallel with the sensor.

8. The electronic device of claim 7, wherein the oscillation generator is configured to generate the excitation oscillation with a second frequency, wherein the second frequency is between about 60 percent and about 140 percent of the first resonant frequency of the first LC oscillator.

9. The electronic device of claim 8, wherein the second frequency is between about 80 percent and about 120 percent of the first resonant frequency of the first LC oscillator.

10. The electronic device of claim 9, wherein the second frequency is between about 95 percent and about 105 percent of the first resonant frequency of the first LC oscillator.

11. The electronic device of claim 2, wherein the oscillation generator includes a second LC oscillator and a clock generator configured to apply to the second LC oscillator a first clock signal or a signal derived from the first clock signal including the first clock frequency and a pre-determinable duty cycle.

12. The electronic device of claim 11, wherein the pre-determinable duty cycle is between about 100 nanoseconds and about 1000 milliseconds.

13.-22. (canceled)

23. The electronic device of claim 1, wherein the device is configured to carry out at least:
periodically generating a plurality of excitation oscillations, by decaying excitation oscillations via the oscillation generator, and
applying the plurality of excitation oscillations to the first measuring resonant circuit, wherein in particular the plurality of excitation oscillations are applicable to the first measuring resonant circuit such that at least one of
a) the first measuring resonant circuit is brought, at least approximately, into resonance with a respective excitation oscillation and
b) the measuring oscillation is obtained as a swelling and subsequently decaying oscillation.

24. The electronic device of claim 1, further comprising:
at least one functional component, and wherein the device is configured to control at least one of an operating state and a change of an operating state of the at least one functional component depending on the movement information.

25. The electronic device of claim 24, wherein the at least one functional component is a measuring device configured to measure layer thicknesses, wherein the measuring device is configured to measure layer thicknesses of at least one of
layers of at least one of lacquer paint rubber, plastic on at least one of steel, iron and cast iron, and
layers of lacquer, paint, rubber, and plastic on non-magnetic base materials including at least one of aluminum, copper and brass.

26. The electronic device of claim 25, wherein the device is configured to carry out at least one layer thickness measurement by the measuring device depending on the movement information.

27. The electronic device of claim 1, wherein the device is configured to at least temporarily deactivate the oscillation generator depending on the movement information.

28. The electronic device of claim 1, wherein the housing includes a substantially circular cylindrical basic shape, and wherein the actuating element includes a substantially hollow cylindrical basic shape and is coaxially surrounding a first axial end region of the housing.

29. The electronic device of claim 28, wherein the sensor coil is arranged inside the housing and at least partially in the first axial end region.

30. (canceled)

31. The electronic device of claim 28, wherein the housing is hermetically sealed at least in the first axial end region.

32. (canceled)
